(19) United States
(12) Patent Application Publication
(10) Pub. No.: US 2026/0157139 A1
(43) Pub. Date: Jun. 4, 2026

(54) SYSTEMS AND METHODS FOR SEPARATING SEMICONDUCTOR WAFERS

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 18/968,439

(22) Filed: Dec. 4, 2024

(51) Int. Cl. H01L 21/67

(52) U.S. Cl. CPC H10P 72/0428; H10P 72/0604

(57) ABSTRACT

Systems and methods are provided for separation bonded first and second semiconductor wafers. The systems include a tool having a tip that includes a first and second members configured to contact the first and second wafers, respectively, sensors configured to sense stress applied by the first and second members, an automated apparatus configured to move the first and second members, and a controller configured to insert the tip of the tool between the wafers, separate the first and second members to apply a force based on a force setting, monitor the stress applied to the wafers, adjust the force setting in response to the stress applied, and remove the tool from between the wafers in response to complete separation thereof or in response to the stress applied to thereto exceeding a maximum stress threshold.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a system for separating semiconductor wafers joined by a wafer bonding process in accordance with some embodiments;

FIG. 2 is a flowchart illustrating an exemplary first method for separating semiconductor wafers joined by a wafer bonding process in accordance with some embodiments;

FIGS. 3-7 include various views of portions of the system of FIG. 1 illustrating various aspects of the first method of FIG. 2 in accordance with some embodiments;

FIG. 8 is a flowchart illustrating an exemplary second method for separating semiconductor wafers joined by a wafer bonding process in accordance with some embodiments;

FIGS. 9-11 represent portions of exemplary tools for the system 100 of FIG. 1 in accordance with some embodiments;

FIG. 12 represents various aspects of a wafer separation process in accordance with some embodiments;

FIGS. 13 and 14 represent various aspects of wafer separation processes that include multiple tools in accordance with some embodiments; and

FIGS. 15-18 illustrate an exemplary method of re-joining semiconductor wafers after separation thereof in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Wafer bonding processes are used in the manufacturing of semiconductor devices where two or more wafers are joined together to create a single, solid wafer structure. This technique may be used in the fabrication of various advanced electronics, microelectromechanical systems (MEMS), sensors, and other high-tech devices. Wafer bonding processes include, for example, direct wafer bonding (fusion bonding), anodic bonding, thermocompression bonding, adhesive bonding, eutectic bonding, and plasma-assisted bonding.

Wafer bonding processes typically have relatively high success rates. However, wafer bonding processes are complex and require precise control over various processing conditions. For example, the wafers must have bonding surfaces that are sufficiently planar and clean with little to no contaminants (e.g., particles, organic residues, etc.), processing chambers must have strict control over temperatures and pressures, and the wafers must have proper alignment. If the wafers are formed of different materials, differences in the coefficient of thermal expansion (CTE) may create additional challenges.

If the result of the wafer bonding process is unsatisfactory, separation processes may be attempted, but the success and ease of separation may depend on several factors, such as the wafer bonding process used, the materials involved, and/or how long the bond has been in place. In some examples, the separation process may include heating, application of solvents, and/or use of mechanical force. However, separation of bonded wafers can be challenging and may result, for example, in damage and/or contamination to the wafers or components thereof (e.g., metal interconnects).

Presented herein are embodiments of systems and methods for separation of semiconductor wafers joined by wafer bonding processes. In various embodiments, the systems include a tool having a tip with a pair of members configured to be inserted between the joined wafers and independently separated while monitoring stress applied to the wafers thereby. In this manner, the wafers may be separated by an automated process without exceeding a maximum stress corresponding to damage of the wafers and/or components thereof.

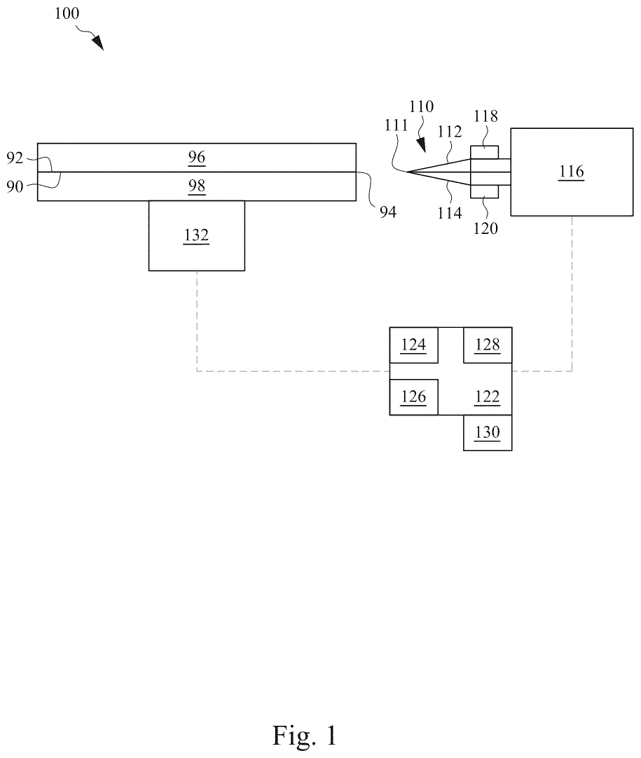

FIG. 1 is a functional block diagram of an example system 100 configured to separate semiconductor wafers joined by wafer bonding processes in accordance with an embodiment. Shown is a wafer structure including a first semiconductor wafer 96 and a second semiconductor wafer 98 joined by wafer bonding. Although in this example the wafer structure includes a pair of joined semiconductor wafers 96, 98, the wafer structure may include more than two semiconductor wafers joined to adjacent wafers by wafer bonding. The first and second semiconductor wafers 96, 98 may be one of a variety of types of semiconductor wafers commonly employed in semiconductor integrated circuit fabrication, and integrated circuits may be formed therein and/or thereupon. The first and second semiconductor wafers 96, 98 may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used. In some examples, the first and second semiconductor wafers 96, 98 are formed of the same materials, and in other examples, the first and second semiconductor wafers 96, 98 are formed of different materials. The first and second semiconductor wafers 96, 98 may be joined by various wafer bonding processes having various parameters. In some examples, the wafer bonding processes may include direct wafer bonding (fusion bonding), anodic bonding, thermocompression bonding, adhesive bonding, eutectic bonding, and plasma-assisted bonding.

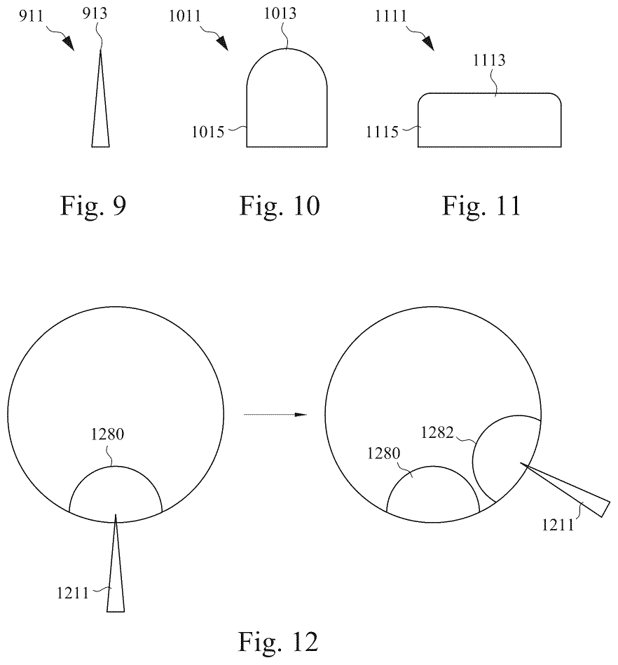

The system 100 may include a tool 110 having a tip 111 configured to be inserted between the first and second semiconductor wafers 96, 98. In particular, the tip 111 may be configured to be inserted into an interface between bonded surfaces 90, 92 of the first and second semiconductor wafers 96, 98 from an edge junction 94 thereof. As such, the tip 111 may include a relative thin portion, at least adjacent to a distal end thereof. In some examples, the tip 111 may increase in thickness in a direction away from the distal end thereof. With such structure, the tip 111 may function as a wedge such that insertion of the tip 111 between the bonded surfaces 90, 92 may result in an increasing separation of the first and second semiconductor wafers 96, 98 with increasing insertion depth. The tip 111 of the tool 110 may have various widths and width-wise shapes. FIGS. 9-11 present exemplary width-wise shapes of tips of tools, such as the tip 111 of the tool 110. In FIG. 9, a first tip 911 has a triangular width-wise shape having a sharp point at a distal end 913 thereof and increasing linearly in width. The first tip 911 may have a needle-like shape. In FIG. 10, a second tip 1011 has a relatively thin or flat, rounded or semicircular distal end 1013 that transitions into an elongated portion 1015 having a constant width. In FIG. 11, a third tip 1111 has a relatively thin or flat, planar distal end 1113 having rounded corners that transition into an elongated portion 1115 having a constant width. The second tip 1011 and/or the third tip 1111 may have blade-like shapes. The tool 110 and/or the tip 111 thereof may be formed of various materials. In some examples, the tool 110 is formed of a material having sufficient material strength, rigidity, and toughness to separate the first and second semiconductor wafers without plastic deformation, fracturing, or breaking. In some examples, the tool 110 may be formed of or include a metallic material such as, but not limited to titanium or alloys thereof.

The tool 110 includes a first member 112 and a second member 114 that may each be individually moved in directions transverse thereto by an automated apparatus 116 functionally coupled thereto. With such arrangement, the tip 111 of the tool 110 may be inserted between the first and second semiconductor wafers 96, 98, and then the automated apparatus 116 may separate the first and second members 112, 114 to force the first and second semiconductor wafers 96, 98 in opposite directions and thereby push them apart. In some examples, automated apparatus 116 may be configured to move the first and second members 112, 114 simultaneously at the same rate of movement, simultaneously at different rates of movement, or individually (i.e., one at a time). The automated apparatus 116 may include various components configured for controlled movement of the first and second members 112, 114 with sufficient force to separate the first and second semiconductor wafers 96, 98.

In some examples, the automated apparatus 116 may control movement of the first and second members 112, 114 based on instructions or commands received from a controller 122. In such examples, the controller 122 includes at least one processor 124, a communication bus 126, and a computer readable storage device or media 128. The processor 124 performs the computation and control functions of the controller 122. The processor 124 can be any custom made or commercially available processor, a central processing unit (CPU), a graphics processing unit (GPU), an auxiliary processor among several processors (124) associated with the controller 122, a semiconductor-based microprocessor (in the form of a microchip or chip set), a macroprocessor, any combination thereof, or generally any device for executing instructions. The computer readable storage device or media 128 may include volatile and nonvolatile storage in read-only memory (ROM), random-access memory (RAM), and/or keep-alive memory (KAM). The computer-readable storage device or media 128 may be implemented using any of a number of known memory devices such as PROMs (programmable read-only memory), EPROMs (erasable PROM), EEPROMs (electrically erasable PROM), flash memory, or any other electric, magnetic, optical, or combination memory devices capable of storing data, some of which represent executable instructions. The bus 126 serves to transmit programs, data, status and other information or signals between the various components of the controller 122. The bus 126 can be any suitable physical or logical means of connecting computer systems and components. This includes, but is not limited to, direct hard-wired connections, fiber optics, infrared, and wireless bus technologies.

The instructions may include one or more separate programs, each of which comprises an ordered listing of executable instructions for implementing logical functions. The instructions, when executed by the processor 124, receive and process signals from sensors, perform logic, calculations, methods and/or algorithms, and generate data based on the logic, calculations, methods, and/or algorithms. Although only one controller 122 is shown in FIG. 1, the system 100 can include any number of controllers that communicate over any suitable communication medium or a combination of communication mediums and that cooperate to process the sensor signals, perform logic, calculations, methods, and/or algorithms, and generate data.

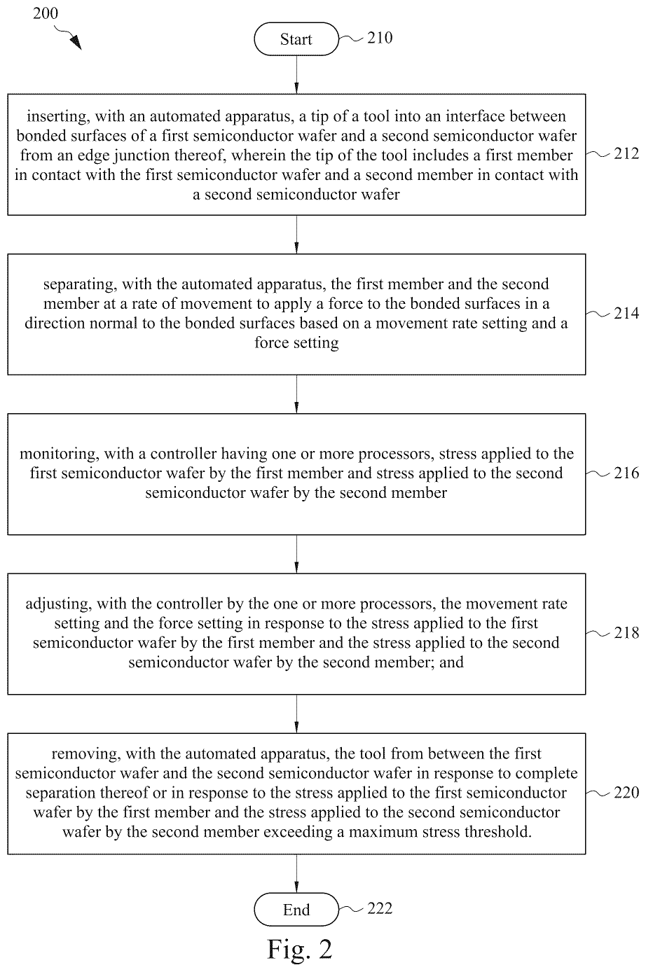

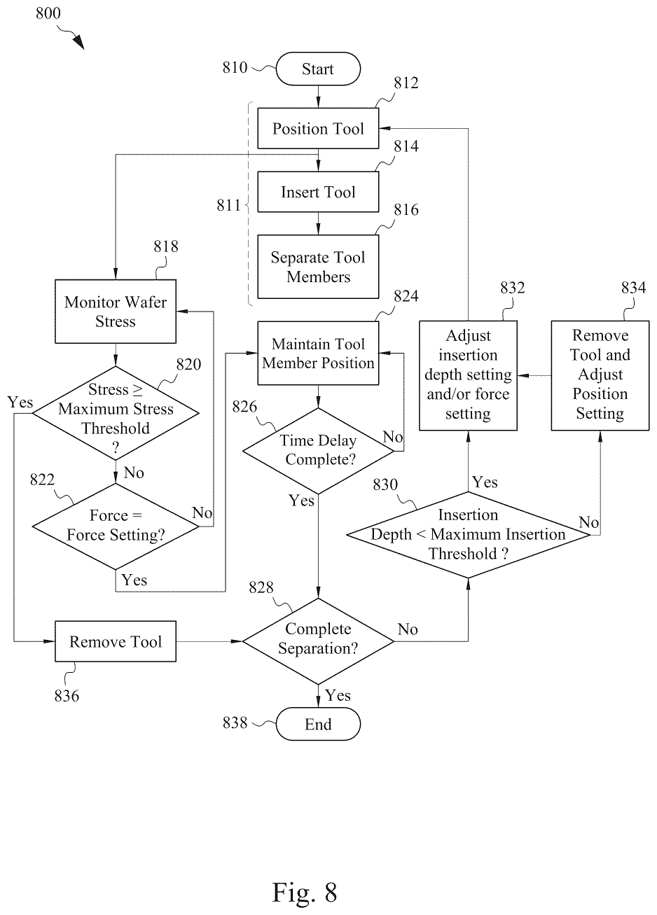

In some examples, a data storage device 130 may be provided to store data for use by the controller 122. The storage device 130 can be any suitable type of storage apparatus, including various different types of direct access storage and/or other memory devices. In one example, the storage device 130 comprises a program product from which a computer readable memory device can receive a program that executes one or more examples of one or more processes of the present disclosure, such as the steps of the process discussed further below in connection with FIGS. 2 and 8. In another example, the program product may be directly stored in and/or otherwise accessed by the memory device and/or one or more other disks and/or other memory devices.

In some examples, the system 100 may include a first sensor 118 functionally coupled with the first member 112 and a second sensor 120 functionally coupled with the second member 114. The first and second sensors 118, 120 are configured to sense, in real-time, stresses applied to the first and second semiconductor wafers 96, 98 by the first and second members 112, 114 during a separation process. The first and second sensors 118, 120 may be in communication with the controller 122 and configured to transmit signals to the controller 122 comprising data indicative of the sensed stress. The controller 122 may be configured to receive the signals, and monitor the sensed stress during the separation process. In some examples, the controller 122 may continuously or periodically compare the sensed stress to one or more thresholds stored in the computer readable storage device or media 128 and/or the data storage device 130. In some examples, the controller 122 compares the sensed stress to a maximum stress threshold to ensure that the stress caused by the first and second members 112, 114 does not cause damage to the first and second semiconductor wafers 96, 98 and/or components thereof.

A workstation 132 may be provided to secure the wafer structure and, optionally, move the wafer structure relative to the tool 110. In some examples, the workstation 132 may be configured to move along along one-, two-, or three-axes. In some examples, the workstation 132 may be functionally coupled with the controller 122 and movement of the workstation 132 may be controlled by the controller 122.

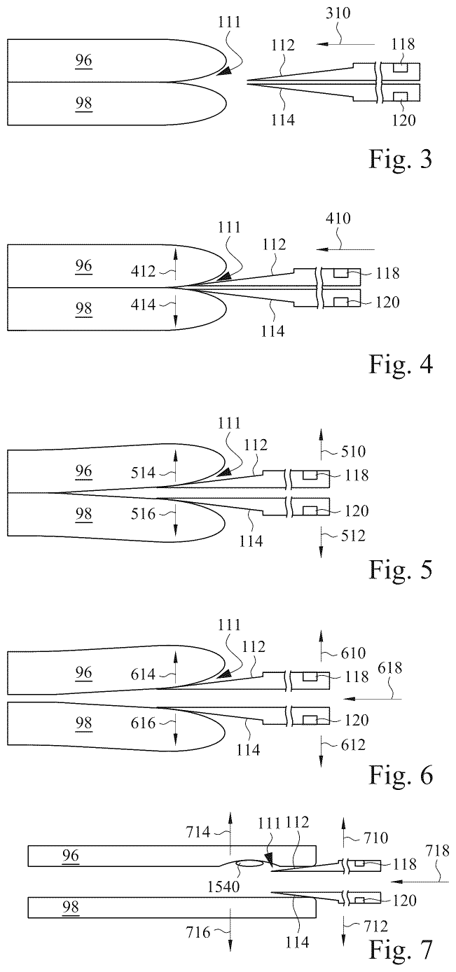

Referring to FIG. 2, an exemplary method 200 is presented for separating wafers joined by a wafer bonding process. For convenience, the method 200 will be described as performed using the system 100 of FIG. 1.; however, the method 200 is not limited to the system 100 of FIG. 1, and may be performed with other systems. Certain aspects of the method 200 will be discussed in reference to FIGS. 3-7 which include cross-sectional views of portions of the wafer structure and the tip 111 of the tool 110. Other portions of the system 100 are omitted for clarity.

The method 200 may start at 210. In some examples, the method 200 may include providing or producing the wafer structure including the first and second semiconductor wafers 96, 98. In such examples, the method 200 may include performing a wafer bonding process such as direct wafer bonding (fusion bonding), anodic bonding, thermocompression bonding, adhesive bonding, eutectic bonding, and plasma-assisted bonding. Once a determination has been made that it would be desirable for the first and second semiconductor wafers 96, 98 to be separated (de-bonded), the wafer structure may be secured on the workstation 132. In some examples, the method 200 may include positioning, with the automated apparatus 116 as instructed by the controller 122, the tip 111 of the tool 110 adjacent to the interface between the bonded surfaces 90, 92 of the first and second semiconductor wafers 96, 98 from the edge junction 94 thereof (movement represented by an arrow 310 in FIG. 3).

At 212, the method 200 may include inserting, with the automated apparatus 116 as instructed by the controller 122, the tip 111 of the tool 110 into the interface between the bonded surfaces 90, 92 (movement represented by an arrow 410 in FIG. 4). In this position, the first member 112 may be in contact with the first semiconductor wafer 96 and not in contact with the second semiconductor wafer 98, and the second member 114 may be in contact with the second semiconductor wafer 98 and not in contact with the first semiconductor wafer 96. If the insertion depth of the tip 111, that is, a dimension between edges of the first and second semiconductor wafers 96, 98 and the distal end of the tip 111, is sufficient to reach portions of the tip 111 that increase in thickness, forces may be applied to the first and second semiconductor wafers 96, 98 (directions of forces represented by arrows 412, 414 in FIG. 4) as a result of the insertion and the first and second semiconductor wafers 96, 98 may be partially separated.

At 214, the method 200 may include separating, with the automated apparatus 116, the first and second members at a rate of movement (movement represented by arrows 510, 512 in FIG. 5) to apply a force (direction of forces represented by arrows 514, 516 in FIG. 5) to the bonded surfaces 90, 92, for example, in a direction normal to the bonded surfaces 90, 92 (or to the first and second members 112, 114) based on a movement rate setting and a force setting. These forces applied on the first and second semiconductor wafers 96, 98 by the first and second members 112, 114 may cause separation of the first and second semiconductor wafers 96, 98. At 216, the method 200 may include monitoring, with the controller 122 having one or more of the processors (124) 124, stress applied to the first semiconductor wafer 96 by the first member 112 and stress applied to the second semiconductor wafer 98 by the second member 114. This function may be achieved by the controller 122 receiving the signals from the first and second sensors 118, 120.

At 218, the method 200 may include adjusting, with the controller 122 by the one or more processors (124) 124, the movement rate setting and the force setting in response to the stress applied to the first semiconductor wafer 96 by the first member 112 and the stress applied to the second semiconductor wafer 98 by the second member 114. In some examples, one or more of the steps 212-218 may be performed multiple times to continue the separation of the first and second semiconductor wafers 96, 98. For example, FIG. 6 represents the first and second members 112, 114 as being inserted further between the first and second semiconductor wafers 96, 98 (movement represented by an arrow 618), the first and second members 112, 114 as being further separated (movement represented by arrows 610, 612), and forces applied to the first and second semiconductor wafers 96, 98 as a result of such movement (direction of forces represented by arrows 614, 616). FIG. 7 represents the first and second members 112, 114 being inserted yet further between the first and second semiconductor wafers 96, 98 (movement represented by an arrow 718), the first and second members 112, 114 being yet further separated (movement represented by arrows 710, 712), and forces applied to the first and second semiconductor wafers 112, 114 as a result of such movement (direction of forces represented by arrows 714, 716). FIG. 7 represents the first and second semiconductor wafers 112, 114 as being completely separated.

At 220, the method 200 may include removing, with the automated apparatus 116 as instructed by the controller 122, the tool 110 from between the first and second semiconductor wafers 96, 98 in response to complete separation thereof (FIG. 7) or in response to the stress applied to the first semiconductor wafer 96 by the first member 112 and/or the stress applied to the second semiconductor wafer 98 by the second member 114 exceeding a maximum stress threshold. In some examples, the maximum stress threshold may be determined experimentally based on, for example, an average of maximum stresses applied to test sample wafer structures prior to damage occurring thereto.

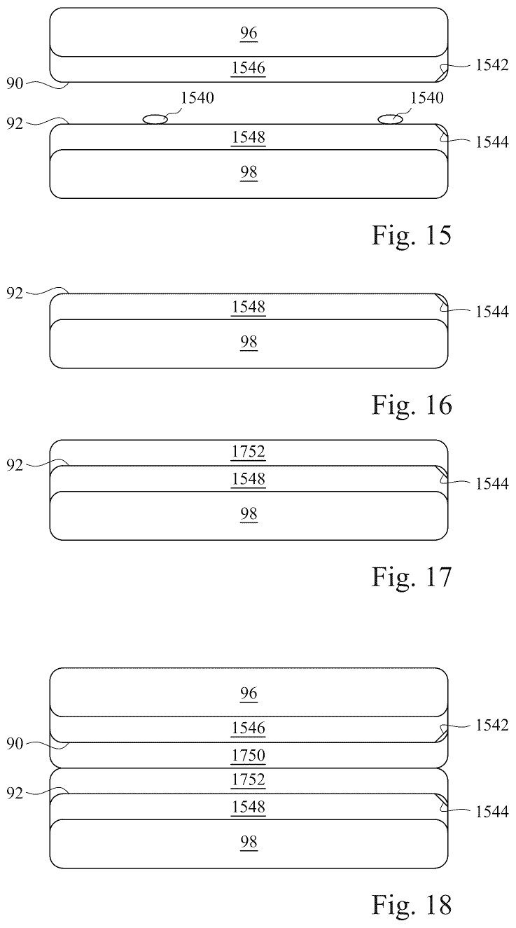

In some examples, the method 200 may include rejoining the first and second semiconductor wafers 96, 98. FIGS. 15-18 illustrate steps in a re-joining process in accordance with various examples. FIG. 15 represents the first and second semiconductor wafers 96, 98 once separated. In this example, the first and second semiconductor wafers 96, 98 include scratches 1542, 1544 resulting from the separation process as well as contaminates and/or defects 1540 on the previously bonded surfaces 90, 92. In some examples, an adhesive or other material (collectively referred to hereinafter as the bonding film 1546, 1548) may remain on the previously bonded surfaces 90, 92 from the original wafer bonding process. Surface preparation may be performed on the previously bonded surfaces 90, 92 such as scrubbing, water flushing, and/or chemical mechanical planarization (CMP). FIG. 16 represents the second semiconductor wafer 98 after a surface preparation process, wherein the contaminates 1540 and portions of the bonding film 1548 and scratches 1544 have been removed (the first semiconductor wafer 96 is omitted for clarity but could be similarly processed). In some examples, additional material may be deposited on the surfaces 90, 92. For example, a new boding film may be formed to facilitate a subsequent wafer bonding process, to achieve a desired water thickness, or both. For example, FIG. 17 represents the second semiconductor wafer 98 as having an additional layer of the bonding film 1752 formed on the surface 92 and FIG. 18 represents the first semiconductor wafer 96 as having an additional layer of the bonding film 1750 formed on the surface 90. A wafer bonding process may then be performed to re-join the first and second semiconductor wafers 96, 98, as represented in FIG. 18. The method 200 may end at 222.

Referring now to FIG. 8, another exemplary method 800 is presented for separating wafers joined by a wafer bonding process. For convenience, the method 800 will be described as performed using the system 100 of FIG. 1; however, the method 800 is not limited to the system 100 of FIG. 1, and may be performed with other systems. Although the following discussion of the method 800 will focus on the separation process, the method 800 may also include providing or producing the wafer structure prior to the wafer separation process, and/or include a re-joining process after the wafer separation process, for example, as described above in the discussion of the method 200.

The method 800 may start at 810. At 811, the method 800 may include performing a separation procedure including one or more steps or actions. In this example, the separation procedure includes steps 812, 814, and 816, described hereinafter.

At 812, the method 800 may include positioning, with the automated apparatus 116 as instructed by the controller 122, the tip 111 of the tool 110 in an insertion position adjacent to the interface between the bonded surfaces 90, 92 of the first and second semiconductor wafers 96, 98 at the edge junction 94 thereof. In some examples, the tip 111 of the tool 110 may be positioned based on a position setting. In some examples, positioning the tip 111 of the tool 110 may be performed in response to a current position of the tip 111 of the tool 110 being different from the position setting (e.g., stored in the computer readable storage device or media 128 and/or the data storage device 130).

At 814, the method 800 may include inserting, with the automated apparatus 116 as instructed by the controller 122, the tip 111 of the tool 110 between the bonded surfaces 90, 92 to an insertion depth, wherein the first member 112 is in contact with the first semiconductor wafer 96 and the second member 114 in contact with the second semiconductor wafer 98.

At 816, the method 800 may include separating, with the automated apparatus 116 as instructed by the controller 122, the first and second members 112, 114 at a rate of movement to apply a force to the bonded surfaces 90, 92 in a direction normal to the bonded surfaces 90, 92 (or to the first and second members 112, 114) based on a movement rate setting and a force setting (e.g., both stored in the computer readable storage device or media 128 and/or the data storage device 130).

At 818, the method 800 may include monitoring, with the controller 122 having one or more of the processors (124) 124, stress applied to the first semiconductor wafer 96 by the first member 112 and stress applied to the second semiconductor wafer 98 by the second member 114. This function may be achieved by the controller 122 receiving, continuously or periodically, the signals from the first and second sensors 118, 120. At 820, the controller 122 may determine whether the stresses applied by the first and/or second members 112, 114 meet or exceed a maximum stress threshold. If, at 820, a determination is made that the maximum stress threshold has been reached, the method 200 may include removing the tool 110 from between the first and second members 112, 114 at 836, and the continue to 828. If, at 820, a determination is made that the maximum stress threshold has not been reached, the controller 122 may determine, at 822, whether the force setting has been reached by the first and second members 112, 114. If, at 822, the force setting has not been reached, the method 800 may return to 818 to continue monitoring the stresses. If, at 822, the force setting has been reached, the method 800 may continue to 824.

At 824, the method 800 may include maintaining, with the automated apparatus as instructed by the controller 122, positions of the first and second members 112, 114 for a time delay (e.g., 3-15 seconds) based on a time delay setting (e.g., stored in the computer readable storage device or media 128 and/or the data storage device 130). At 826, the controller 122 may determine whether the time delay is complete. If, at 826, a determination is made that the time delay has not yet completed, the method 800 may continue at 824 to maintain the position of the first and second members 112, 114. Once the time delay has been completed at 826, the method 800 may continue to 828.

At 828, the method 800 may include determining whether complete separation of the first and second semiconductor wafers 96, 98 has been achieved. If, at 828, a determination is made that complete separation has not been achieved, the method 800 may continue to 830.

At 830, the controller 122 may determine whether the insertion depth of the tip 111 of the tool 110 is equal to a maximum insertion threshold. If, at 830, a determination is made that the insertion depth is less than the maximum insertion threshold, the method 800 may continue to 832.

At 832, the method 800 may include adjusting, with the controller 122, the insertion depth setting, the movement rate setting, and/or the force setting. For example, the insertion depth setting may be increased such that the tip 111 of the tool 110 is subsequently further inserted between the first and second semiconductor wafers 96, 98. As another example, the movement rate setting and/or the force setting may be decreased to subsequently perform additional separation of the first and second semiconductor wafers 96, 98 while not causing damage thereto. In some examples, one or more of these settings may be adjusted based on the stress applied to the first semiconductor wafer 96 by the first member 112 and the stress applied to the second semiconductor wafer 98 by the second member 114. The method 800 may then return to 812 to repeat the separation procedure using the adjusted settings.

If, at 830, a determination is made that the insertion depth is equal to the maximum insertion threshold, the method 800 may continue to 834. At 834, the method 800 may include removing, with the automated apparatus 116 as instructed by the controller 122, the tool 110 from between the first and second semiconductor wafers 96, 98, and adjusting the position setting. By removing the tool 110 and adjusting the position setting, the separation procedure 811 may be repeated at a different position of the wafer structure. For example, FIG. 12 illustrates a first separation procedure being performed with a tip 1211 of a tool at a first position (left-side image) on a circular wafer structure to separate a first region 1280, and then subsequently being repeated at a second position (right-side image) to separate a second region 1282. The separation procedure 811 may be performed a plurality of times to gradually separate the first and second semiconductor wafers 96, 98 and thereby reduce a likelihood of damage occurring thereto. The method 800 may then continue to 832. If, at 828, a determination is made that complete separation has been achieved, the method 800 may end at 838. It is understandable that the first region 1280 may be smaller than the first region 1280 shown in the figure. For example, the first region 1280 may not overlap with the active chip area. The total area of all first region(s) 1280 may be less than 50% of the total wafer area.

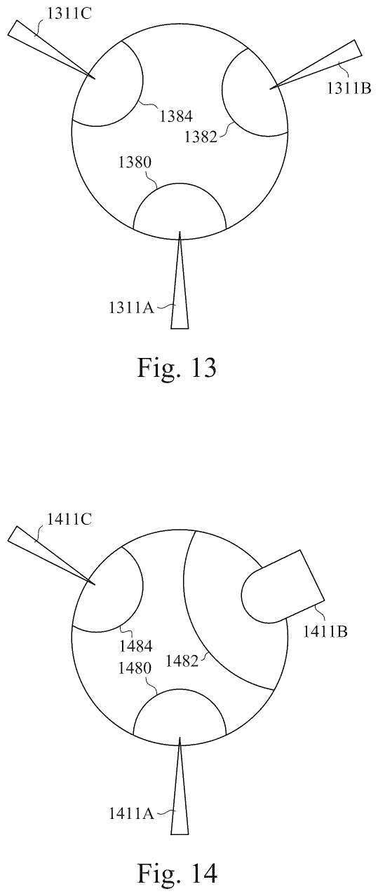

The methods 200 and 800 are described above in reference to a single tool 110. However, the systems and methods herein, including the system 100 and the methods 200, 800, are not limited to a single tool, and may include utilize two or more tools simultaneously. For example, FIG. 13 presents a separation procedure being performed on a circular wafer structure using three tools 1311A-C disposed at three different positions about the circular wafer structure to separate three different regions 1380, 1382, 1384. In this example, each of the tools 1311A-C have identical tips (e.g., a sharp point similar to the example of FIG. 9). However, the tools may have tips with different shapes and sizes. For example, FIG. 14 presents a separation procedure being performed on a circular wafer structure using three tools 1411A-C disposed at three different positions about the circular wafer structure to separate three different regions 1480, 1482, 1484 wherein two of the tools 1411A, 1411C are identical (e.g., a sharp point similar to the example of FIG. 9) and the third tool 1411B is different (e.g., a flat, rounded distal end similar to the example of FIG. 10).

The present disclosure therefore provides systems and methods for separating semiconductor wafers joined by wafer bonding processes.

In accordance with an embodiment, a system is provided for use during a semiconductor manufacturing process. In one example, the system includes a tool having a tip that includes a first member and a second member, wherein the first member is configured to handle a first semiconductor wafer and the second member is configured to handle a second semiconductor wafer, wherein the first semiconductor wafer and the second semiconductor wafer are joined by a wafer bonding process, sensors configured to sense stress applied to the first semiconductor wafer by the first member and stress applied to the second semiconductor wafer by the second member, an automated apparatus configured to independently move the first member and the second member in directions transverse to each other, and a controller in operable communication with the sensors and the automated apparatus. The controller is configured to, by one or more processors, insert, with the automated apparatus, the tip of the tool into an interface between bonded surfaces of the first semiconductor wafer and the second semiconductor wafer from an edge junction thereof, separate, with the automated apparatus, the first member and the second member to apply a force to the bonded surfaces based on a force setting, monitor, based on signals received from the sensors, the stress applied to the first semiconductor wafer by the first member and the stress applied to the second semiconductor wafer by the second member, adjust the force setting in response to the stress applied to the first semiconductor wafer by the first member and the stress applied to the second semiconductor wafer by the second member, and remove, with the automated apparatus, the tool from between the first semiconductor wafer and the second semiconductor wafer in response to separation thereof or in response to the stress applied to the first semiconductor wafer by the first member and the stress applied to the second semiconductor wafer by the second member exceeding a maximum stress threshold.

In accordance with another embodiment, a method is provided use during a semiconductor manufacturing process. In one example, the method includes inserting a tip of a tool into an interface between bonded surfaces of a first semiconductor wafer and a second semiconductor wafer from an edge junction thereof, wherein the tip of the tool includes a first member handing the first semiconductor wafer and a second member handling the second semiconductor wafer, separating the first member and the second member to apply a force to the bonded surfaces to the bonded surfaces based on a force setting, monitoring, with a controller having one or more processors, stress applied to the first semiconductor wafer by the first member and stress applied to the second semiconductor wafer by the second member, adjusting, with the controller by the one or more processors, the force setting in response to the stress applied to the first semiconductor wafer by the first member and the stress applied to the second semiconductor wafer by the second member, and removing, with the automated apparatus, the tool from between the first semiconductor wafer and the second semiconductor wafer in response to complete separation thereof or in response to the stress applied to the first semiconductor wafer by the first member and the stress applied to the second semiconductor wafer by the second member exceeding a maximum stress threshold.

In accordance with yet another embodiment, a method is provided for use during a semiconductor manufacturing process. In one example, the method includes performing a separation procedure including positioning a tip of a tool in an insertion position adjacent to an interface between bonded surfaces of a first semiconductor wafer and a second semiconductor wafer at an edge junction thereof, wherein the tip of the tool is positioned based on a position setting, wherein positioning the tip of the tool is performed in response to a current position of the tip of the tool being different from the position setting, inserting the tip of the tool between the bonded surfaces to an insertion depth, wherein the tip of the tool includes a first member configured to handle the first semiconductor wafer and a second member configured to handle the second semiconductor wafer, and then separating the first member and the second member to apply a force to the bonded surfaces based on a force setting. The method includes monitoring, with a controller having one or more processors, stress applied to the first semiconductor wafer by the first member and stress applied to the second semiconductor wafer by the second member, maintaining positions of the first member and the second member for a time delay based on a time delay setting upon the first member and the second member achieving the force indicated by the force setting, upon expiration of the time delay, adjusting, with the controller having the one or more processors, the position setting in response to a current insertion depth being equal to a maximum insertion depth setting, adjusting, with the controller having the one or more processors, the insertion depth setting and the force setting based on the stress applied to the first semiconductor wafer by the first member and stress applied to the second semiconductor wafer by the second member, optionally repeating the separation procedure in response to adjustment of one or more of the position setting, the insertion depth setting, and the force setting, and removing the tool from between the first semiconductor wafer and the second semiconductor wafer in response to separation thereof or in response to the stress applied to the first semiconductor wafer by the first member and the stress applied to the second semiconductor wafer by the second member being equal to or exceeding a maximum stress threshold.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system, comprising:
a tool having a tip that includes a first member and a second member, wherein the first member is configured to handle a first semiconductor wafer and the second member is configured to handle a second semiconductor wafer, wherein the first semiconductor wafer and the second semiconductor wafer are bonded at bonded surfaces thereof;
sensors configured to sense stress applied to the first semiconductor wafer by the first member and stress applied to the second semiconductor wafer by the second member;
an automated apparatus configured to independently move the first member and the second member in directions transverse to each other; and
a controller in operable communication with the sensors and the automated apparatus and configured to, by one or more processors:
insert, with the automated apparatus, the tip of the tool into an interface between the bonded surfaces of the first semiconductor wafer and the second semiconductor wafer from an edge junction thereof;
separate, with the automated apparatus, the first member and the second member to apply a force to the bonded surfaces in a direction normal to the bonded surfaces a force setting;
monitor, based on signals received from the sensors, the stress applied to the first semiconductor wafer by the first member and the stress applied to the second semiconductor wafer by the second member;
adjust the force setting in response to the stress applied to the first semiconductor wafer by the first member and the stress applied to the second semiconductor wafer by the second member; and
remove, with the automated apparatus, the tool from between the first semiconductor wafer and the second semiconductor wafer in response to separation thereof or in response to the stress applied to the first semiconductor wafer by the first member and the stress applied to the second semiconductor wafer by the second member exceeding a maximum stress threshold.

2. The system of claim 1, wherein the tip of the tool increases in thickness from a distal end thereof.

3. The system of claim 1, wherein the tip of the tool has triangular width-wise shape having a sharp point at a distal end.

4. The system of claim 1, wherein the tip of the tool has a semicircular distal end that transitions into an elongated portion having a constant width.

5. The system of claim 1, wherein the tip of the tool has a planar distal end that transitions into an elongated portion having a constant width.

6. The system of claim 1, wherein the tool is a first tool, wherein the system includes an additional tool having a tip that includes a third member and a fourth member, wherein the third member is configured to handle the first semiconductor wafer and the fourth member is configured to handle the second semiconductor wafer, wherein the additional tool is configured to be used in a separation process simultaneously with the tool.

7. The system of claim 1, wherein the controller is configured to, with the one or more processors, prior to adjusting the force setting, maintaining positions of the first member and the second member for a time delay based on a time delay setting upon the first member and the second member achieving the force indicated by the force setting.

8. The system of claim 1, further comprising a workstation configured for securing the first semiconductor wafer and the second semiconductor wafer, wherein the controller is configured to, by the one or more processors, move the workstation relative to the tool.

9. A method, comprising:
inserting a tip of a tool into an interface between bonded surfaces of a first semiconductor wafer and a second semiconductor wafer from an edge junction thereof, wherein the tip of the tool includes a first member to handle the first semiconductor wafer and a second member to handle the second semiconductor wafer;
separating the first member and the second member to apply a force to the bonded surfaces in a direction normal to the bonded surfaces based on a force setting;
monitoring, with a controller having one or more processors, stress applied to the first semiconductor wafer by the first member and stress applied to the second semiconductor wafer by the second member;
adjusting, with the controller by the one or more processors, the force setting in response to the stress applied to the first semiconductor wafer by the first member and the stress applied to the second semiconductor wafer by the second member; and
removing the tool from between the first semiconductor wafer and the second semiconductor wafer in response to separation thereof or in response to the stress applied to the first semiconductor wafer by the first member and the stress applied to the second semiconductor wafer by the second member exceeding a maximum stress threshold.

10. The method of claim 9, further comprising, prior to adjusting the force setting, maintaining, with an automated apparatus, positions of the first member and the second member for a time delay based on a time delay setting upon the first member and the second member achieving the force indicated by the force setting.

11. The method of claim 9, wherein inserting the tip of the tool into the interface and separating the first member and the second member are at least part of a separation process, wherein the method includes repeating the separation process.

12. The method of claim 9, further comprising:
inserting a tip of an additional tool into the interface between the bonded surfaces of the first semiconductor wafer and the second semiconductor wafer from a second edge junction thereof, wherein the tip of the additional tool includes a third member to handle the first semiconductor wafer and a fourth member to handle the second semiconductor wafer; and
separating the third member and the fourth member to apply a second force to the bonded surfaces in a direction normal to the bonded surfaces based on a second force setting.

13. The method of claim 12, wherein the tip of the tool has a first shape, and the tip of the additional tool has a second shape that is different from the first shape.

14. The method of claim 9, wherein the tip of the tool increases in thickness from a distal end thereof, and inserting the tip of the tool into the interface between the bonded surfaces increases the force applied from the tip on the bonded surfaces.

15. A method comprising:
performing a separation procedure including:
positioning a tip of a tool in an insertion position adjacent to an interface between bonded surfaces of a first semiconductor wafer and a second semiconductor wafer at an edge junction thereof, wherein the tip of the tool is positioned based on a position setting, wherein positioning the tip of the tool is performed in response to a current position of the tip of the tool being different from the position setting;
inserting the tip of the tool between the bonded surfaces to an insertion depth, wherein the tip of the tool includes a first member to handle the first semiconductor wafer and a second member to handle the second semiconductor wafer, wherein insertion depth is based on an insertion depth setting; and then
separating the first member and the second member to apply a force to the bonded surfaces based on a force setting;
monitoring, with a controller having one or more processors, stress applied to the first semiconductor wafer by the first member and stress applied to the second semiconductor wafer by the second member;
maintaining positions of the first member and the second member for a time delay based on a time delay setting upon the first member and the second member achieving the force indicated by the force setting;
upon expiration of the time delay, adjusting, with the controller having the one or more processors, the position setting in response to a current insertion depth being equal to a maximum insertion depth setting;
adjusting, with the controller having the one or more processors, the insertion depth setting, and the force setting based on the stress applied to the first semiconductor wafer by the first member and stress applied to the second semiconductor wafer by the second member; and
removing the tool from between the first semiconductor wafer and the second semiconductor wafer in response to separation thereof or in response to the stress applied to the first semiconductor wafer by the first member and the stress applied to the second semiconductor wafer by the second member being equal to or exceeding a maximum stress threshold.

16. The method of claim 15, further comprising performing a wafer bonding process to join the first semiconductor wafer and the second semiconductor wafer prior to performing the separation procedure.

17. The method of claim 15, further comprising:
performing a surface preparation process on the first semiconductor wafer and the second semiconductor wafer after complete separation thereof; and
performing a wafer bonding process to rejoin the first semiconductor wafer and the second semiconductor wafer.

18. The method of claim 15, further comprising repeating the separation procedure in response to adjustment of one or more of the position setting, the insertion depth setting, and the force setting prior to removing the tool.

19. The method of claim 15, further comprising performing a second separation procedure with a second tool simultaneously with the separation procedure.

20. The method of claim 15, wherein the tip of the tool increases in thickness from a distal end thereof, and inserting the tip of the tool into the interface between the bonded surfaces increases the force applied from the tip on the bonded surfaces.
